(19) United States
(12) Patent Application Publication
(10) Pub. No.: US 2007/0290373 A1
(43) Pub. Date: Dec. 20, 2007

(54) Multilayer bonding ribbon

(76) Inventors: Manfred Reinold, Schwieberdingen (DE); Thomas Kaden, Schwieberdingen (DE); Immanuel Mueller, Gomaringen (DE)

Correspondence Address: KENYON & KENYON LLP, ONE BROADWAY, NEW YORK, NY, 10004, US

(21) Appl. No.: 11/810,330

(22) Filed: Jun. 4, 2007

(30) Foreign Application Priority Data
Jun. 2, 2006 (DE) 10 2006 025 870.3

(51) Int. Cl. H01L 23/52

(52) U.S. Cl. 257/784

(57) ABSTRACT

A bonding wire takes the form of a ribbon, and a bond includes such a bonding wire. The bonding wire includes at least two layers having different current carrying capacity.

### CROSS-REFERENCE TO RELATED APPLICATIONS

The present application claims priority to Application No. 10 2006 025 870.3, filed in the Federal Republic of Germany on Jun. 2, 2006, which is expressly incorporated herein in its entirety by reference thereto.

### FIELD OF THE INVENTION

The present invention relates to a bonding wire taking the form of a ribbon for bonding microelectronic components and/or contact surfaces.

### BACKGROUND INFORMATION

Bonding wires are lead wires for microelectronic components such as integrated circuits or LEDs. Particularly in microelectronic assembly and interconnection technology, the bonding wire is often made of gold or a gold alloy. However, bonding wires made of aluminum, usually having a small silicon content, are also used. A major application is the connection of pins, visible from the outside in the case of a chip, to pads situated in the interior of the chip. For this application, usually bonding wires having a circular cross section with a diameter between approximately 25 and 50 μm are used. In addition to bonding wires having a circular cross section, so-called ribbons having a rectangular cross section are also used. As a rule, the flexibility, and therefore the service life of bonding wires in the form of ribbons is higher than for bonding wires having a circular cross section. Usually, bonding wires in the form of ribbons also exhibit a higher current carrying capacity, that is, the blowing current is higher than for comparable bonding wires having a circular cross section. In power electronics, nearly pure aluminum bonding wires are often used. Bonding wires having a circular cross section are used here as well, as a rule the diameter of the bonding wires for power electronics applications being between 125 and 500 μm. In addition to the bonding wires having a circular cross section, bonding wires in the form of ribbons are increasingly being used in power electronics. When choosing the material for the bonding wires, often a compromise must be found between good bondability and sufficient current carrying capacity.

German Published Patent Application No. 42 32 742 describes a bonding wire having a circular cross section, that has a core made of gold or copper, the core being provided with a coating of aluminum or aluminum oxide having a layer thickness between 5 nm and 100 nm. The copper core provides for high current carrying capacity, while the coating allows reliable contacting or welding to the contact surfaces. The coated bonding wire exhibits higher tensile strength than a corresponding bonding wire that is not coated.

Especially to permit the transmission of high currents, frequently a plurality of side-by-side bonding wires are used, having a circular cross section with a diameter of up to 500 μm. Bonding the many individual wires is time and cost intensive. In addition, the space available is often not sufficient for this purpose. The thick bonding wires used, having a circular cross section, are extremely susceptible to stress due to vibration and temperature fluctuations.

### SUMMARY

Example embodiments of the present invention provide a bonding wire that is designed especially for transmitting high currents, can be welded reliably, and has a service life that is as long as possible and an area expanse that is as small as possible.

According to example embodiments of the present invention, a bonding wire takes the form of a ribbon, in multilayers, the layers being made of different material. In so doing, e.g., the layer having greater current carrying capacity is made of copper and/or gold, whereas the layer producing the contact, thus the layer to be welded to a contact surface of a microelectronic component or contact, is made of silver, and/or tin, and/or aluminum, and/or copper, and/or copper alloys, and/or nickel, and/or gold. The bonding may be carried out by feeding at least one pulse of ultrasonic energy and/or by feeding heat. Alternatively or additionally, the bonding may be accomplished by exerting pressure. For example, the bonding wire in the form of a ribbon may be bonded using the wedge-wedge bonding method, the ball/wedge bonding method or the ball/ball bonding method. In particular, the different layers of the bonding wire in the form of a ribbon are aligned exclusively parallel to one another. Given such an arrangement in a bonding wire having a rectangular cross section, the layer producing the contact to a contact surface has a large contact area. Because of the arrangement of the bonding wire in the form of a ribbon, the at least two layers may be selected such that the layer producing the contact is able to be welded as reliably and contacted as well as possible, while the at least one further layer has high current carrying capacity. Based on the increased current carrying capacity of the further layer, the bonding wire in the form of a ribbon may be thinner overall than if it were made of only one layer. The flexibility and therefore the service life of the ribbon may thereby be increased. The sensitivity with respect to stress due to vibration and/or temperature fluctuations therefore drops considerably compared to conventional ribbons made of a single uniform material. For example, it is possible for the layer producing the contact to be made as a thin aluminum layer or gold layer or nickel layer or platinum layer, and for the layer having greater current carrying capacity to be made of gold and/or copper. The thickness of such a bonding wire is substantially less than if the bonding wire were made exclusively of aluminum.

The melting point of the varied layer materials may be different. For example, the melting point of the layer producing the contact to the microelectronic component is lower than the melting point of the layer having the increased current carrying capacity.

The conductivity of the at least two different layers may be different from each other. For example, the conductivity of the layer having the increased current carrying capacity may be higher.

It may be provided that the bending resistance and/or the tensile strength, thus the tensile force which is needed to tear through the individual layer, and/or the elasticity of the layers or of the layer material is different. It is therefore possible to produce ribbon bonding wires particularly suited for the respective application case.

The thickness of the at least two layers may be different. For example, the layer having greater current carrying capacity is thicker than the layer producing the contact. By varying the thickness of the layers, it is possible to vary not only the current carrying capacity of the layers, but also their flexibility. The total thickness of the bonding wire is reduced considerably by the use of a material exhibiting exceptional current carrying capacity, such as copper or gold.

The bonding wire may have a sandwich type of construction, and may have at least three layers, e.g., two outer layers and at least one layer in between. For example, the middle layer or one of the middle layers may have more current carrying capacity than the outer layers. Given a bonding wire formed in this manner, it is unimportant whether the contact to a microelectronic component is produced with the one or the other opposite flat side. A sandwich wire of this type exhibits exceptional current carrying capacity and unsusceptibility to stress due to vibration and temperature fluctuation. For example, the layers are aligned in parallel to one another, the thickness of the outer layers being less than their width. For example, a multilayer bonding wire in the form of a ribbon may be produced using a hot rolling method. The different layers may be positioned exclusively parallel to one another, and therefore may be visible in a side view of the wire, thus, may be carried to the outer side of the wire. It is also possible to coat the middle layer, for example, galvanically. In this instance, the cross-sectional area is only approximately rectangular. The two opposite outer layers may be made of the same material.

The outer layers may have a lower melting point than the at least one inner layer. Such a bonding wire is able to be welded reliably to a contact surface.

The conductivity and/or the bending resistance and/or the tensile strength and/or the elasticity may be different for the outer and inner layers. The parameters may be selected such that the bonding wire may be welded and contacted reliably, and the middle layer may exhibit a high current carrying capacity. Due to the material combination, the bonding wire may be more flexible overall than if it were made only of one uniform material.

A bond may include at least one previously described bonding wire. In this context, the broad side of the bonding wire in the contact area may be aligned parallel to the contact surfaces to be contacted.

Further features and aspects of example embodiments of the present invention are described in more detail below with reference to the appended Figures.

### BRIEF DESCRIPTION OF THE DRAWINGS

FIG. 1 illustrates a bond, using a bonding wire taking the form of a ribbon.

FIG. 2 illustrates a bonding ribbon enclosed over the entire periphery by an outer layer.

### DETAILED DESCRIPTION

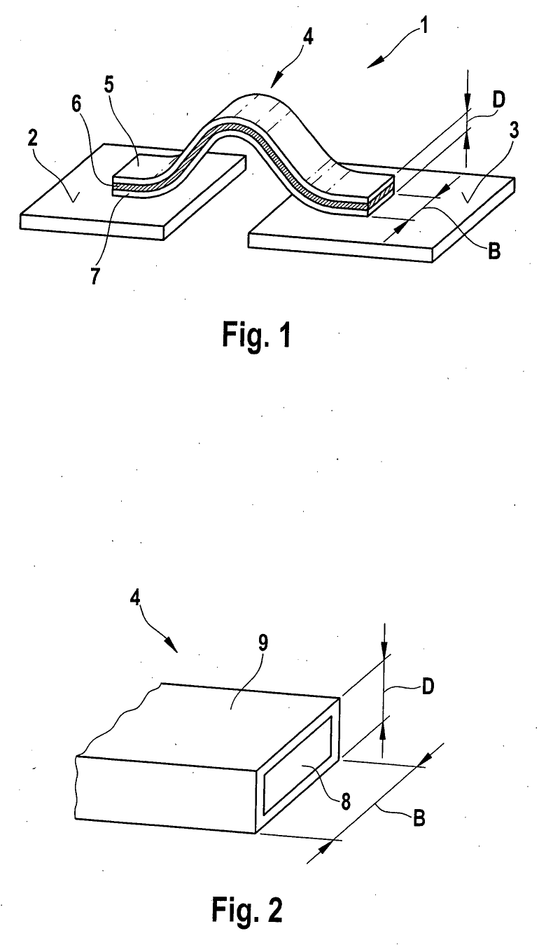

FIG. 1 illustrates a connection 1 between two contact surfaces 2, 3. For example, contact surface 2 is the pad of a chip, and contact surface 3 is the associated pin. Contact surfaces 2, 3 are electroconductively interconnected via a bonding wire 4 in the form of a ribbon.

Bonding wire 4 is made up of three layers 5, 6, 7, layers 5, 6, 7 being joined to each other over the entire surface. In this exemplary embodiment, outer two layers 5, 7 are made of aluminum, while the inner layer accommodated in sandwich fashion between outer layers 5, 7 is made of copper. Inner or middle layer 6 has a higher current carrying capacity than the two outer layers 5, 7. This means that the blowing current of middle layer 6 is higher than the maximum current of outer layers 5, 7 needed for the blowout.

Thickness D of bonding wire 4 taking the form of a ribbon is less than its width B. Due to the sandwich arrangement with inner copper layer 6, given higher or at least equal current carrying capacity of bonding wire 4, thickness D of bonding wire 4 in the form of a ribbon is substantially less than if the bonding wire were made exclusively of aluminum and did not have a multilayer construction. This is attributable to the feature that, given equal current carrying capacity, layer 6 having greater current carrying capacity may be made thinner than if layer 6 were made of aluminum.

Because aluminum is used as material for outer layers 5, 7, bonding wire 4 may be bonded reliably to contact surfaces 2, 3, e.g., using ultrasound.

Layers 5, 6, 7 are aligned parallel to one another, middle layer 6 having no direct contact with contact surfaces 2, 3. The contact is produced exclusively via outer lower layer 7 in the drawing plane.

The ribbon bonding wire illustrated in FIG. 1 is considerably more flexible than a bonding wire made completely of aluminum, which means its ultimate tensile strength is increased. Therefore, the bonding wire illustrated in FIG. 1 is substantially more unsusceptible to stress due to vibration and temperature fluctuation.

The bonding wire may be particularly suitable for use in power electronics for transmitting high currents. One possible main field of application is hybrid drive technology.

Bonding wire 4 illustrated in FIG. 1 requires substantially less space than a corresponding number of side-by-side bonding wires having a circular cross section, in order to be able to transmit the same maximum current. Furthermore, bonding wire 4 has a large contact area to contact surfaces 2, 3, which extends over the entire width of bonding wire 4.

FIG. 2 illustrates an example embodiment of a multilayer bonding ribbon 4. The bonding ribbon is formed with a rectangular cross section and has a core, thus an inner layer 8. In contrast to the arrangement illustrated in FIG. 1 in which parallel layers are provided exclusively, inner layer 8 is enclosed over its entire periphery by an outer layer 9. In this exemplary embodiment, inner layer 8 is made of copper or a copper alloy. Outer layer 9 is made of aluminum or an aluminum alloy. In contrast to the bonding ribbon illustrated in FIG. 1, outer layer 9 is extremely thin and encloses inner layer 8 over the entire periphery, that is, on four sides. The end faces are not coated, since the bonding ribbon is wound off from a roll and cut off. Outer layer 9 is extremely thin compared to inner layer 8. Thickness D of bonding ribbon 4 is, e.g., approximately 30 μm. The average layer thickness of the outer layer is, e.g., only approximately 23 nm. Outer layer 9 may be applied, for example, by a sputter method, galvanically or by roll-bonded cladding, etc. Outer layer 9 prevents oxidation and improves bondability. Ribbon 4, coated over its entire periphery by extremely thin outer layer 9, provides that it exhibits good bonding properties with respect to the surface, and in addition, brings with it the good deformation properties of a ribbon, e.g., good planar welding capability with little deformation. Therefore, ribbon 4 illustrated in FIG. 2 may be particularly suitable for bonding soft, delicate surfaces, e.g., ICs. The ribbon illustrated may be bonded using a standard ribbon bonder.

What is claimed is:

1. A bonding wire, comprising:
at least two layers made of different materials, the bonding wire taking the form of a ribbon.

2. The bonding wire according to claim 1, wherein the layers exhibit different current carrying capacities.

3. The bonding wire according to claim 1, wherein the layers have different melting points.

4. The bonding wire according to claim 1, wherein the layers have difference conductivities.

5. The bonding wire according to claim 1, wherein the layers have different at least one of (a) bending resistances, (b) tensile strengths and (c) elasticities.

6. The bonding wire according to claim 1, wherein the layers have different thicknesses.

7. The bonding wire according to claim 1, wherein the bonding wire includes at least three layers.

8. The bonding wire according to claim 1, wherein the bonding wire includes two outer layers and at least one inner layer arranged between the outer layers, the inner layer having a greater current carrying capacity than the outer layers.

9. The bonding wire according to claim 8, wherein the outer layers have a lower melting point than the inner layer.

10. The bonding wire according to claim 8, wherein one of (a) the inner layer has at least one of (i) a higher conductivity, (ii) a lower bending resistance, (iii) a lower tensile strength and (iv) a lower elasticity than the outer layers and (b) the outer layers have at least one of (i) a higher conductivity, (ii) a lower bending resistance, (iii) a lower tensile strength and (iv) a lower elasticity than the inner layer.

11. The bonding wire according to claim 8, wherein the outer layer encloses the inner layer over an entire periphery.

12. The bonding wire according to claim 11, wherein an average layer thickness of the outer layer is one of (a) between approximately 1 nm and 200 nm, (b) between approximately 15 nm and 30 nm and (c) between approximately 20 nm and 25 nm.

13. The bonding wire according to claim 8, wherein an average layer thickness of the outer layer is less than 1/10 of an average thickness of the bonding wire.

14. The bonding wire according to claim 1, wherein an average thickness of the bonding wire is approximately 25 μm to 300 μm.

15. The bonding wire according to claim 1, wherein an average width of the bonding wire is approximately 50 μm to 1 mm.

16. A bond between two contact surfaces, wherein the contact surfaces are interconnected by at least one bonding wire, the bonding wire including at least two layers made of different materials, the bonding wire taking the form of a ribbon.

17. The bond according to claim 16, wherein the contact surfaces are bonded by an ultrasonic weld.
